(19) United States
(12) Patent Application Publication
(10) Pub. No.: US 2024/0290631 A1
(43) Pub. Date: Aug. 29, 2024

(54) METHOD FOR MANUFACTURING A LEAD FRAME AND STRUCTURE THEREOF

(71) Applicant: SHENZHEN SIPTORY TECHNOLOGY CO., LTD, Shenzhen (CN)

(72) Inventor: Dongdong Shao, Shenzhen (CN)

(21) Appl. No.: 18/657,850

(22) Filed: May 8, 2024

Related U.S. Application Data
(63) Continuation of application No. PCT/CN2022/131778, filed on Nov. 14, 2022.

(30) Foreign Application Priority Data
Nov. 12, 2021 (CN) 202111339289.6

(51) Int. Cl. H01L 21/48; H01L 23/495

(52) U.S. Cl. CPC H01L 21/4821; H01L 23/49534; H01L 23/49548

(57) ABSTRACT

The present invention discloses a method for manufacturing a lead frame, comprising providing a first plating resistant layer on the surface of a frame substrate, providing a first recess on the first plating resistant layer, filling the first recess to obtain a first protruding platform, providing a second plating resistant layer on the first protruding platform and the first plating resistant layer, providing a second recess on the second plating resistant layer, filling the second recess, providing a capping structure on the first protruding platform; the capping structure, first protruding platform, and frame substrate form an I-shape structure, which reduces the probability of delamination and cracking.

### CROSS REFERENCE TO RELATED APPLICATIONS

The present application is a Continuation Application of PCT Application No. PCT/CN2022/131778 filed on Nov. 14, 2022, which claims the benefit of Chinese Patent Application No. 202111339289.6 filed on Nov. 12, 2021. All the above are hereby incorporated by reference in their entirety.

### TECHNICAL FIELD

The present invention relates to the field of packaging technology, specifically to a method for manufacturing a lead frame and a structure of the lead frame.

### BACKGROUND ART

The frame is widely used in the field of semiconductor packaging. As a chip packaging carrier, it realizes electrical interconnection between chips and circuits inside and outside a packaging body through bonding materials.

### SUMMARY

### Technical Problem

According to the traditional subtractive etching processing technology for frames, frame substrate 1 binds to chip carrying protruding platform 4, and mostly forms a structure similar to inverted T (as shown in FIGS. 1-2). When there is a lack of control in the semiconductor packaging processing (such as material surface oxidation, abnormal plastic packaging parameters, etc.), the contact surface of zigzag-shape frame 5 and plastic packaging body 3, i.e. the zigzag-shape contact surface 51, as shown in FIGS. 2-3, is prone to delamination and cracking under stress, thereby affecting product yield and quality.

### Technical Solution

The examples of the present invention provide a method for manufacturing a lead frame and a lead frame structure, which enhances the bonding force between the lead frame and the plastic packaging body and reduces the probability of delamination and cracking.

### Advantageous Effects

A method for manufacturing a lead frame, comprising:
Step A. providing a first plating resistant layer on the surface of the frame substrate, exposing and developing the first plating resistant layer to obtain a first recess;
Step B. adding layers by addition method, filling the first recess by electroplating, chemical deposition or sputtering to obtain a first protruding platform;
Step C. providing a second plating resistant layer on the first protruding platform and the first plating resistant layer, exposing and developing the second plating resistant layer to obtain a second recess which is located at the upper part of the first protruding platform, with a portion of the second recess located at the upper part of the first plating resistant layer;
Step D. adding layers by addition method, filling the second recess by electroplating, chemical deposition or sputtering to form a capping structure on the first protruding platform;
Step E. removing the first and second plating resistant layers.

Preferably, the method further comprises after Step A and before Step B:
Step A1. treating the inner wall of the opening of the first recess using radio frequency plasma processing to increase its roughness;

Preferably, in Step A1: the roughness of the side wall of the first recess is controlled in the range of: Rz=2-3 μm, Ra=0.2-0.3 μm.

Preferably, the method further comprises after Step C and before Step D:
Step C1. using dielectric barrier discharge (DBD) plasma processing to improve surface tension and hydrophilicity of the inner wall of the opening of the second recess; treating the plating resistant materials using dielectric barrier plasma, improving the surface tension and hydrophilicity at the corner where two plating resistant materials (the first and second plating resistant layers) are connected, ensuring sufficient penetration and exchange of the electroplating solution or other solutions, and ensuring electroplating quality.

The strength of the DBD plasma processing applied to the corner where the first and second plating resistant layers bind is more than 10% greater than that of other portions, and the processing time is more than 10% longer than that of other portions.

Preferably, Step D comprises:
Step D1. adding layers by addition method, filling the second recess by electroplating, chemical deposition or sputtering to form a first metal layer of the capping structure on the first protruding platform;

Preferably, the method further comprises after Step D1:
Step D2. adding layers by addition method, filling the second recess by electroplating, chemical deposition or sputtering to form a second metal layer of the capping structure on the first metal layer;

Preferably, the strength and hardness of the first metal layer are greater than those of the second metal layer.

Preferably, the first metal layer is a gold layer, a nickel-palladium gold layer, or a nickel layer, and the second metal layer is a copper layer.

Preferably, Step D comprises:
controlling the roughness of the inner wall of the second recess in the range of: Rz=2-3 μm, Ra=0.2-0.3 μm;

The thickness of the first metal layer is 3-5 μm.

Preferably, Step E comprises: removing the first and second plating resistant layers by high pressure cleaning and APPA atmospheric pressure plasma cleaning;

APPA atmospheric pressure plasma cleaning is introduced, which uses a plasma beam with a high energy density to directly act on the corner where the first and second plating resistant layers bind, separating any residual plating resistant material from the corner of the frame.

Preferably, the height of the first protruding platform is 80% to 95% of the depth of the first recess; the surface of the first protruding platform is roughened before the capping structure is produced; the capping structure includes a vertical portion and a platform portion, with the vertical portion located directly above the first protruding platform and the platform portion located at the upper part of the vertical portion;

Preferably, the bound surface between the first protruding platform and the capping structure is indented.

A lead frame structure comprises a frame substrate, a first protruding platform, and a capping structure, where the first protruding platform is set on the frame substrate, the periphery of the first protruding platform is a recess, and the capping structure is set on the first protruding platform. At least a portion of the capping structure protrudes from the upper part of the first protruding platform and covers the recess.

Preferably, the number of the first protruding platforms and capping structures is both more than 2, with one first protruding platform corresponding to one capping structure; and the first protruding platform distributed in an array on the frame substrate;

The capping structure, first protruding platform, and frame substrate form an I-shape structure.

Preferably, the side walls of the first protruding platform and capping structure are arranged in a serrated shape.

It can be seen from the above technical solutions that the examples of the present invention have the following advantages:

A method for manufacturing a lead frame, comprising: providing a first plating resistant layer on the surface of the frame substrate, exposing and developing the first plating resistant layer to obtain a first recess; filling the first recess by electroplating, chemical deposition or sputtering to obtain a first protruding platform; providing a second plating resistant layer on the first protruding platform and the first plating resistant layer, exposing and developing the second plating resistant layer to obtain a second recess which is located at the upper part of the first protruding platform, with a portion of the second recess located at the upper part of the first plating resistant layer; filling the second recess by electroplating, chemical deposition or sputtering, and forming a capping structure on the first protruding platform; removing the first and second plating resistant layers, wherein the capping structure, first protruding platform, and frame substrate form an I-shape structure, which can increase the bound surface between the lead frame and the plastic packaging body, reduce the stress between the lead frame and the plastic packaging body, enhance the bonding force between the lead frame and the plastic packaging body, and reduce the probability of delamination and cracking.

Enhanced structural strength: the new lead frame structure has obvious advantages in product structural strength. For one thing, when there is a lack of control during the packaging process (such as frame oxidation, abnormal fluctuations in plastic packaging parameters, or other conventional issues), and for another, when packaged products are actually applied in varying temperature and humidity or even extreme environments such as high and low temperatures, due to the larger bound surface between the plastic packaging body and the lead frame and more uniform and reasonable stress, the new structural frame can effectively enhance the strength of the contact surface between the frame and the plastic packaging body, and improve the overall product structural strength. High reliability performance: when the product of the new lead frame structure has interfacial microcracks, the longer gap channels can effectively delay the occurrence of defects that lead to product failure and prolong the product life cycle.

### DESCRIPTION OF DRAWINGS

To provide a clearer description of the technical solutions in the examples of the present invention, a brief introduction to the drawings required in the description of the examples is given below. Obviously, the drawings described below are only some examples of the present invention. For those skilled in the art, other drawings can also be obtained based on these drawings without inventive efforts.

FIG. 1 is a schematic diagram of the lead frame structure in the prior art.

FIG. 2 is a schematic diagram of the packaged lead frame structure in the prior art.

FIG. 3 is a locally enlarged image of part A of FIG. 2.

FIG. 4 is a schematic diagram of the frame substrate in Example 1 according to the method for manufacturing a lead frame of the present invention.

FIG. 5 is a schematic diagram after Step A in Example 1 according to the method for manufacturing a lead frame of the present invention.

FIG. 6 is a schematic diagram after Step B in Example 1 according to the method for manufacturing a lead frame of the present invention.

FIG. 7 is a schematic diagram after Step D in Example 1 according to the method for manufacturing a lead frame of the present invention.

FIG. 8 is a schematic diagram of the packaged lead frame in Example 1 according to the method for manufacturing a lead frame of the present invention.

FIG. 9 is a locally enlarged image of part B of FIG. 8 in the present invention.

FIG. 10 is a schematic diagram after Step D in Example 2 according to the method for manufacturing a lead frame of the present invention.

FIG. 11 is a locally enlarged image of part C of FIG. 10 in the present invention.

FIG. 12 is a schematic diagram after Step D in Example 3 according to the method for manufacturing a lead frame of the present invention.

FIG. 13 is a locally enlarged image of part D of FIG. 12 in the present invention.

FIG. 14 is a schematic diagram of the packaged lead frame of another example according to the method for manufacturing a lead frame of the present invention.

FIG. 15 is a locally enlarged image of part E of FIG. 14 in the present invention.

FIG. 16A is a schematic diagram of the first plating resistant layer 21 provided by the present invention after the roughness of the side wall of the plating resistant material is shaped under RF plasma conditions after development.

FIG. 16B is a schematic diagram of the corner where the first plating resistant layer 21 and the second plating resistant layer 22 provided by the present invention bind.

FIG. 16C is an indicative diagram of the first plating resistant layer 21 provided by the present invention during plasma treatment after development.

FIG. 16D is an indicative diagram of the first plating resistant layer 21 and the second plating resistant layer 22 provided by the present invention during dielectric barrier discharge (DBD) plasma treatment after development.

FIG. 16E is a local schematic diagram of the lead frame of an example provided by the present invention after treatment by a plasma related process.

FIG. 16F is a local schematic diagram of the lead frame of another example provided by the present invention after treatment by a plasma related process.

FIG. 16G is an indicative diagram of atmospheric pressure plasma arc cleaning of the first plating resistant layer 21 and the second plating resistant layer 22 according to the method for manufacturing a lead frame of the present invention after the production of the capping structure 14.

FIG. 16H is a local schematic diagram of the lead frame obtained after the step shown in FIG. 16G and Step E according to the method for manufacturing a lead frame provided by the present invention.

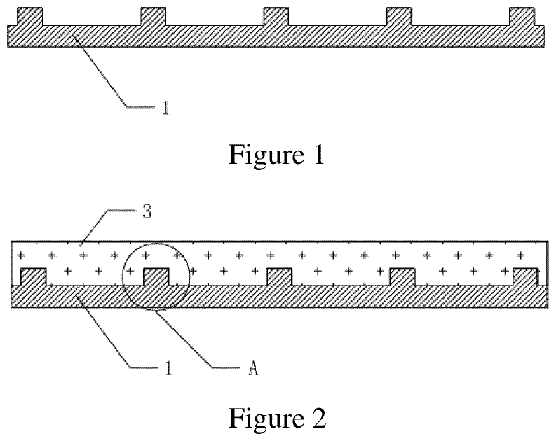

In the figures:

1-a frame substrate; 11-a first recess; 12-a first protruding platform; 13-a second recess; 14-a capping structure; 141-a first metal layer; 142-a second metal layer; 143-a vertical portion; 144-a platform portion; 21-a first plating resistant layer; 22-a second plating resistant layer; 3-a plastic packaging body; 5-a zigzag-shape frame; 51-a zigzag-shape contact surface; 6-an I-shape structure; 61-an I-shape contact surface; 8-an indented structure.

### BEST MODES FOR CARRYING OUT THE INVENTION

A method for manufacturing a lead frame, comprising:
Step A. providing a first plating resistant layer 21 on the surface of the frame substrate 1, exposing and developing the first plating resistant layer 21 to obtain a first recess 11;
Step B. adding layers by addition method, filling the first recess 11 by electroplating, chemical deposition or sputtering to obtain a first protruding platform 12;
Step C. providing a second plating resistant layer 22 on the first protruding platform 12 and the first plating resistant layer 21, exposing and developing the second plating resistant layer 22 to obtain a second recess 13 which is located at the upper part of the first protruding platform 12, with a portion of the second recess 13 located at the upper part of the first plating resistant layer 21;
Step D. adding layers by addition method, filling the second recess 13 by electroplating, chemical deposition or sputtering to form a capping structure 14 on the first protruding platform 12;
Step E. removing the first plating resistant layer 21 and the second plating resistant layer 22.

The strength of the DBD plasma processing applied to the corner where the first plating resistant layer 21 and the second plating resistant layer 22 bind is more than 10% greater than that of other portions, and the processing time is more than 10% longer than that of other portions.

### Embodiments of the Present Invention

The examples of the present invention provide a method for manufacturing a lead frame and a structure of the lead frame for solving the problems of high stress and easy occurrence of microcracks in current lead frames.

A clear and complete description of the technical solutions in the examples of the present invention is provided below by combining with the drawings in the examples of the present invention. Obviously, the described examples are only a part of the examples of the present invention, rather than all of them. Based on the examples in the present invention, the other examples obtained by those skilled in the art without inventive efforts all fall within the protection scope of the present invention.

The terms “first”, “second”, “third”, “fourth”, etc. (if present) in the specification and claims of the present invention as well as in the above figures, are used to distinguish similar objects, not for describing specific orders or sequences. It should be understood that the data used in this way can replace each other in appropriate cases, so that the examples described here can be implemented in a sequence other than those illustrated or described here. In addition, terms “comprising” and “having”, as well as any variations thereof, are intended to cover non-exclusive inclusion. For example, a process, method, system, product, or device that comprises a series of steps or units is not limited to those clearly listed steps or units, but may include other steps or units that are not clearly listed or are inherent to such processes, methods, products, or devices.

Please refer to the drawings. The present invention provides a detailed introduction to the manufacture method and structure of the lead frame through the examples.

### EXAMPLE 1

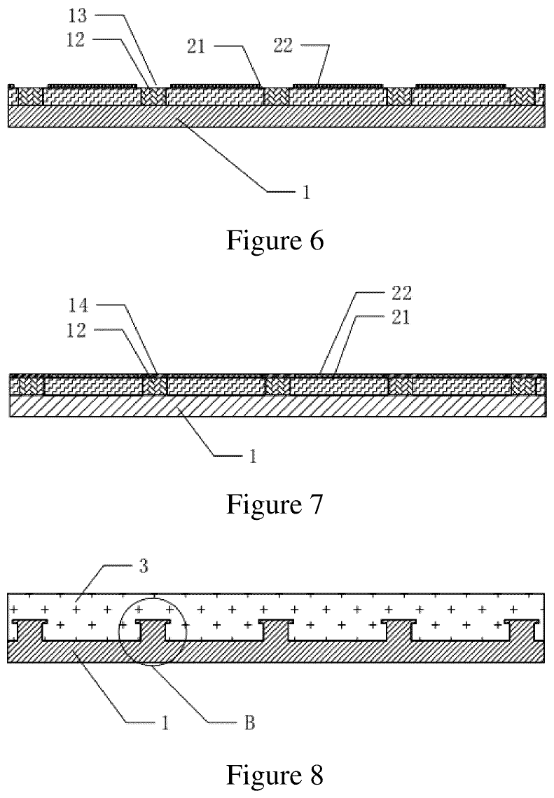

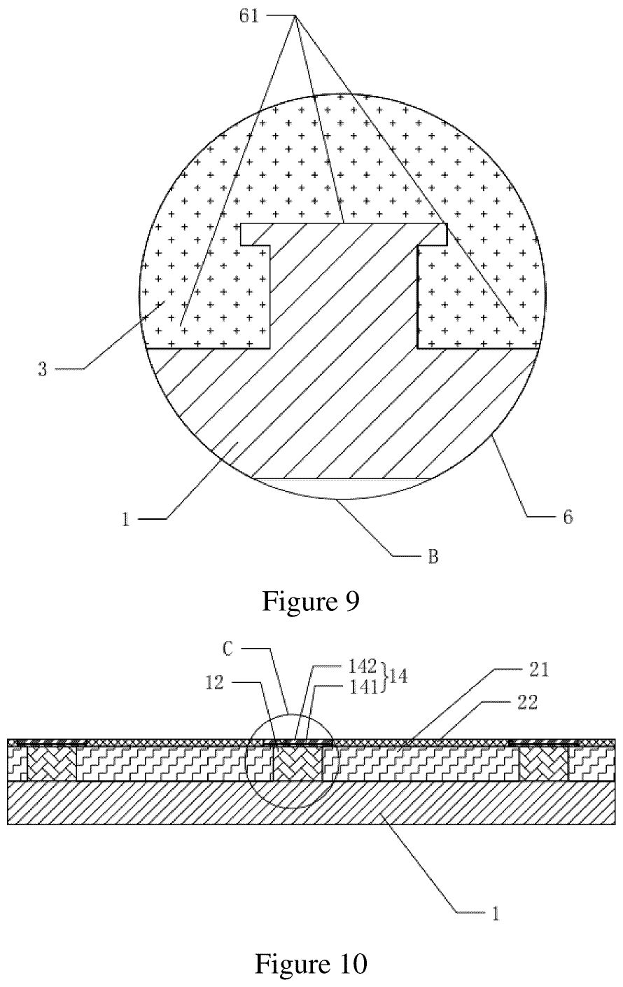

Please refer to FIGS. 4-9. The specific process of the example is as follows:

A method for manufacturing a lead frame, comprising:
Step A. providing a first plating resistant layer 21 on the surface of the frame substrate 1, exposing and developing the first plating resistant layer 21 to obtain a first recess 11;
Step B. adding layers by addition method, filling the first recess 11 by electroplating, chemical deposition or sputtering to obtain a first protruding platform 12;
Step C. providing a second plating resistant layer 22 on the first protruding platform 12 and the first plating resistant layer 21, exposing and developing the second plating resistant layer 22 to obtain a second recess 13 which is located at the upper part of the first protruding platform 12, with a portion of the second recess 13 located at the upper part of the first plating resistant layer 21;
Step D. adding layers by addition method, filling the second recess 13 by electroplating, chemical deposition or sputtering to form a capping structure 14 on the first protruding platform 12;
Step E. removing the first plating resistant layer 21 and the second plating resistant layer 22.

The example further comprises after Step A and before Step B:
Step A1. treating the inner wall of the opening of the first recess 11 using radio frequency plasma processing to increase its roughness; controlling the roughness of the side wall of the first recess 11 in the range of: Rz=2-3 μm, Ra=0.2-0.3 μm.

The example further comprises after Step C and before Step D:
Step C1. using dielectric barrier discharge (DBD) plasma processing to improve surface tension and hydrophilicity of the inner wall of the opening of the second recess 13;

The strength of the DBD plasma processing at the corner where the first plating resistant layer 21 and second plating resistant layer 22 bind is more than 10% greater than that of other portions, and the processing time is more than 10% longer than that of other portions.

In the example, the number of the first protruding platform 12 and the capping structure 14 is both more than 2, with one first protruding platform 12 corresponding to one capping structure 14;

The first protruding platform 12 is distributed in an array on the frame substrate 1;

The capping structure 14, first protruding platform 12, and frame substrate 1 form an I-shape structure 6 which makes the plastic packaging body 3 and the frame substrate 1 form an I-shape contact surface 61.

In the example, Step D comprises: controlling the roughness of the inner wall of the second recess 13 in the range of: Rz=2-3 μm, Ra=0.2-0.3 μm;

The thickness of the first metal layer 141 is 3-5 μm.

In the example, Step E comprises: removing the first plating resistant layer 21 and second plating resistant layer 22 by high pressure cleaning and APPA atmospheric pressure plasma cleaning;

APPA atmospheric pressure plasma cleaning is introduced, which uses a plasma beam with a high energy density to directly act on the corner where the first plating resistant layer 21 and second plating resistant layer 22 bind, separating any residual plating resistant material from the corner of the frame.

### EXAMPLE 2

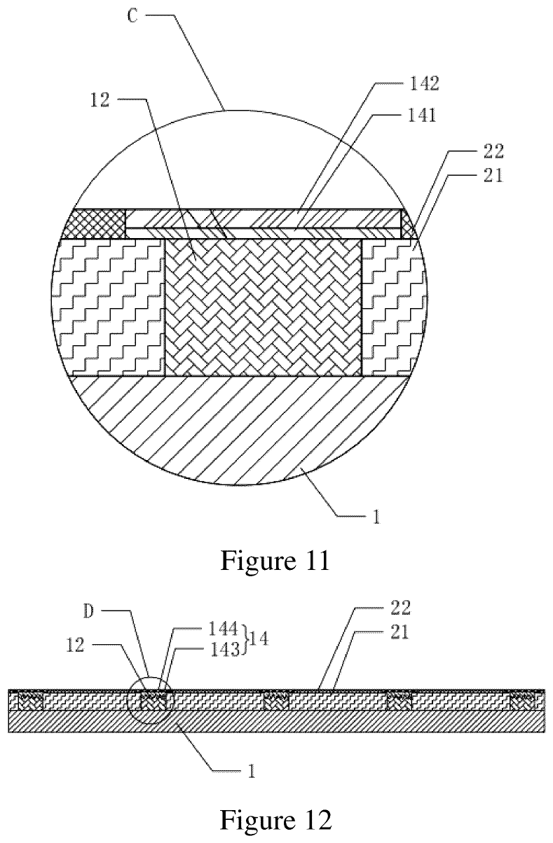

Please refer to FIGS. 4-11. Contents not introduced in this example are the same as those in Example 1.

In the example, Step D comprises:
Step D1. adding layers by addition method, filling the second recess 13 by electroplating, chemical deposition or sputtering to form a first metal layer 141 of the capping structure on the first protruding platform 12;
Step D2. adding layers by addition method, filling the second recess 13 by electroplating, chemical deposition or sputtering to form a second metal layer 142 of the capping structure on the first metal layer 141;

The strength and hardness of the first metal layer 141 are greater than those of the second metal layer 142.

The first metal layer 141 is a gold layer, a nickel-palladium gold layer, or a nickel layer, and the second metal layer is a copper layer.

### EXAMPLE 3

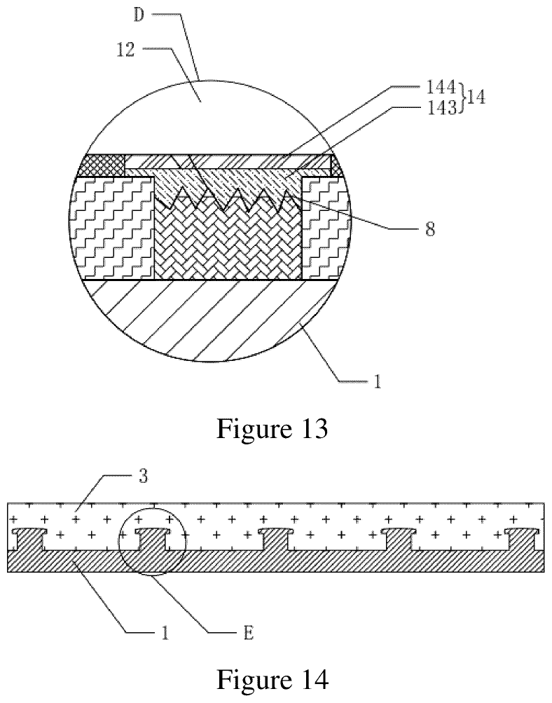

Please refer to FIGS. 4-9 and 12-13. Contents not introduced in this example are the same as those in Example 1.

In the example, the height of the first protruding platform 12 is 80% to 95% of the depth of the first recess 11; the surface of the first protruding platform 12 is roughened before the capping structure 14 is produced; the capping structure 14 includes a vertical portion 143 and a platform portion 144, with the vertical portion located directly above the first protruding platform 12 and the platform portion 144 located at the upper part of the vertical portion 143;

Usually, the first protruding platform 12 is composed of copper or aluminum, and the capping structure 14 normally can also adopt the same structure as the first protruding platform 12. In this example, the first protruding platform 12 is made of copper, and the capping structure 14 includes a vertical portion 143 made of transitional metals, such as copper alloy, nickel alloy, or nickel-palladium gold, and a platform portion 144 that correspondingly adopts copper, nickel, or gold, or the vertical portion 143 is made of soft gold, while the platform portion 144 is made of hard gold. This ensures the bonding force between the first protruding platform 12 and the capping structure 14, and also allows the capping structure 14 to maintain sufficient adaptability with the first protruding platform 12.

The bound surface between the first protruding platform 12 and the capping structure 14 is an indented structure 8.

### EXAMPLE 4

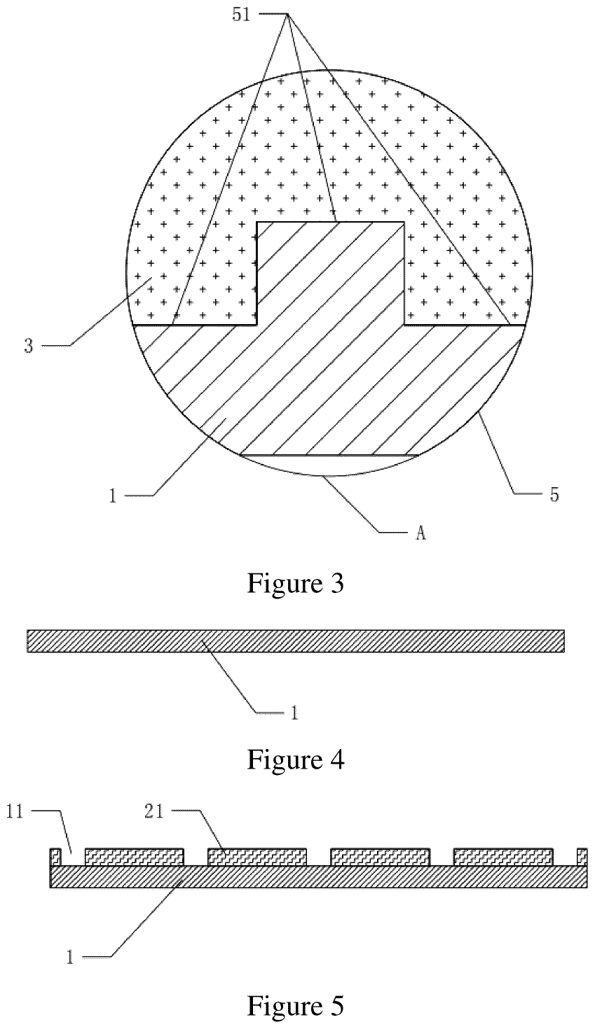

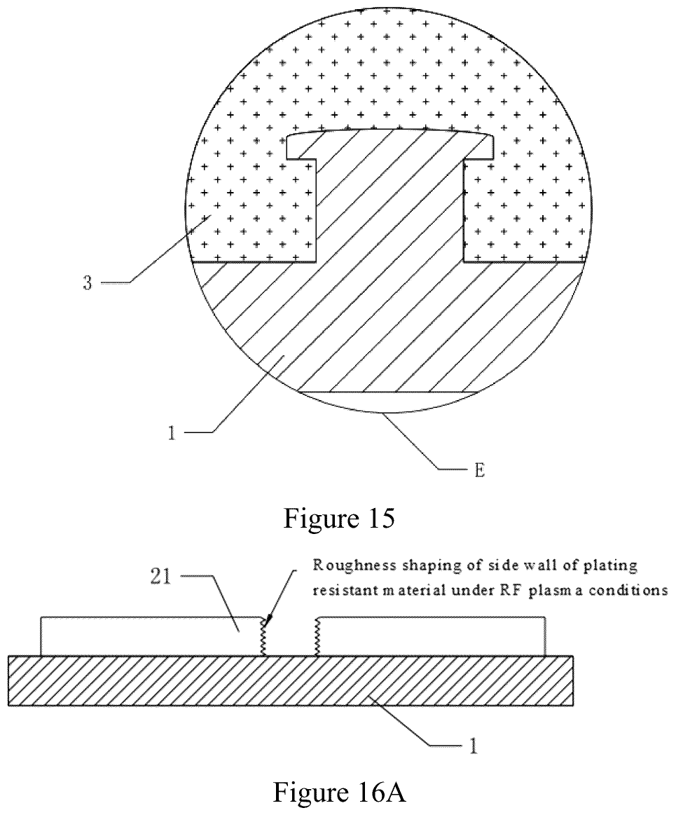

Please refer to FIGS. 3-9 and 14-15. Contents not introduced in this example are the same as those in Example 1.

In the example, the number of the first protruding platform 12 and capping structure 14 is both more than 2, with one first protruding platform 12 corresponding to one capping structure 14;

The first protruding platform 12 is distributed in an array on the frame substrate 1;

The capping structure 14, first protruding platform 12, and frame substrate 1 form an I-like structure whose surface is an arc, and the side of the I-like structure forms an arc to reduce the stress between the I-like structure and the plastic packaging body 3. The I-like structure makes the plastic packaging body 3 and the frame substrate 1 form an I-like contact surface.

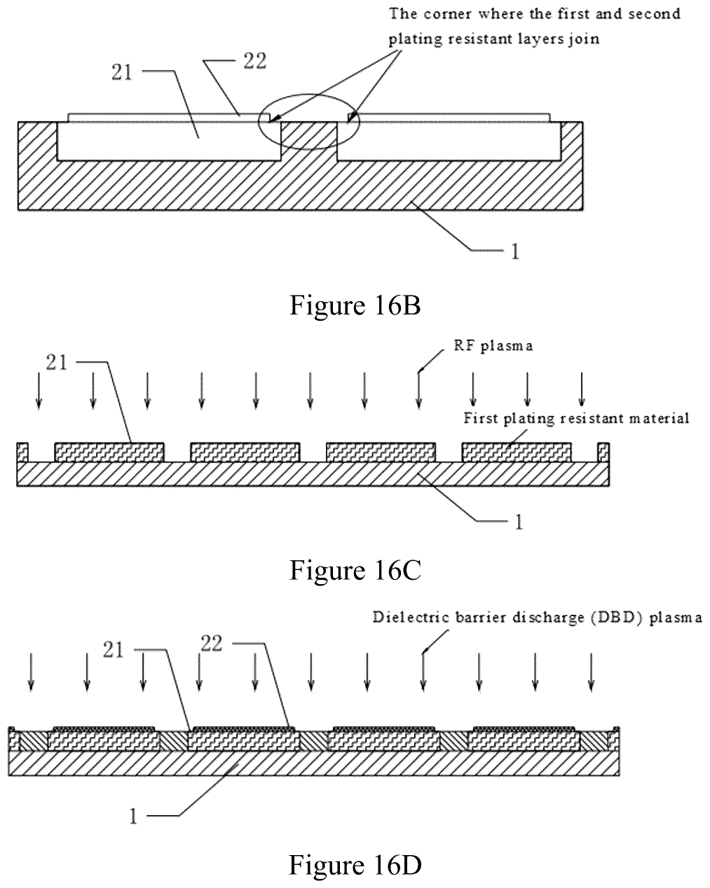

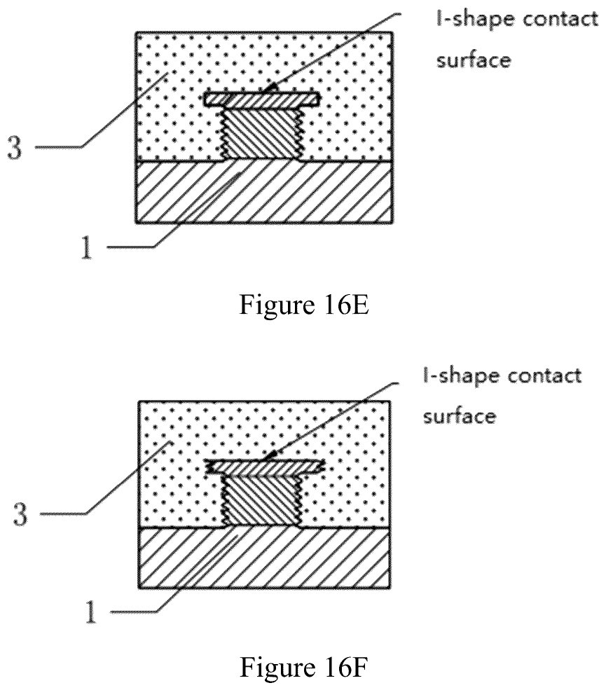

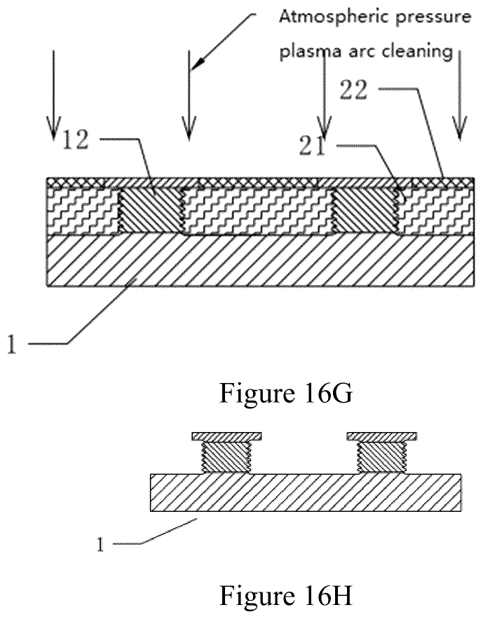

The figures of other examples are shown in FIGS. 16A to 16H, and the structure is treated in different steps using the plaza process.

A lead frame structure comprises a frame substrate 1, a first protruding platform 12, and a capping structure 14, where the first protruding platform 12 is set on the frame substrate 1, the periphery of the first protruding platform 12 is a recess, and the capping structure 14 is set on the first protruding platform 12. At least a portion of the capping structure 14 protrudes from the upper part of the first protruding platform 12 and covers the recess.

In the example, the number of the first protruding platform 12 and capping structure 14 is both more than 2, with one first protruding platform 12 corresponding to one capping structure 14;

The first protruding platform 12 is distributed in an array on the frame substrate 1;

The capping structure 14, first protruding platform 12, and frame substrate 1 form an I-shape structure 6 which makes the plastic packaging body 3 and the frame substrate 1 form an I-shape contact surface 61.

In the example, the side walls of the first protruding platform 12 and capping structure 14 are arranged in a serrated shape.

The technical problem to be solved by the present invention is to develop a novel lead frame structure and production method, which method can be used to produce a frame with high reliability, low cost, flexible design and a wide range of applications: 1. Enhanced structural strength: the new lead frame structure has remarkable advantages in product structural strength. For one thing, when there is a lack of control during the encapsulating process (such as frame oxidation, abnormal fluctuations in plastic packaging parameters, or other conventional issues), and for another, when packaged products are actually applied in varying temperature and humidity or even extreme environments such as high and low temperatures, the new structural frame can effectively enhance the strength of the contact surface between the frame and the plastic packaging body, and improve the overall product structural strength. 2. High reliability performance: when the product of the new lead frame structure has interfacial microcracks, the longer gap channels can effectively delay the occurrence of defects that lead to product failure and prolong the product life cycle.

The above examples are only used to describe the technical solutions of the present invention, and not to limit them; Although the present invention has been described in detail with reference to the above examples, those ordinarily skilled in the art should understand that they can still amend the technical solutions recited in the above examples or equivalently replace some of the technical features thereof; these amendments or replacements do not make the essences of the corresponding technical solutions deviate from the spirit and scope of the technical solutions in the examples of the present invention.

### INDUSTRIAL APPLICABILITY

A method for manufacturing a lead frame, comprising: providing a first plating resistant layer on the surface of the frame substrate, exposing and developing the first plating resistant layer to obtain a first recess; filling the first recess by electroplating, chemical deposition or sputtering to obtain a first protruding platform; providing a second plating resistant layer on the first protruding platform and the first plating resistant layer, exposing and developing the second plating resistant layer to obtain a second recess which is located at the upper part of the first protruding platform, with a portion of the second recess located at the upper part of the first plating resistant layer; filling the second recess by electroplating, chemical deposition or sputtering to form a capping structure on the first protruding platform; removing the first and second plating resistant layers, where the capping structure, first protruding platform, and frame substrate form an I-shape structure, which can increase the bound surface between the lead frame and the plastic packaging body, reduce the stress between the lead frame and the plastic packaging body, enhance the bonding force between the lead frame and the plastic packaging body, and reduce the probability of delamination and cracking.

Enhanced structural strength: the new lead frame structure has remarkable advantages in product structural strength. For one thing, when there is a lack of control during the packaging process (such as frame oxidation, abnormal fluctuations in plastic packaging parameters, or other conventional issues), and for another, when packaged products are actually applied in varying temperature and humidity or even extreme environments such as high and low temperatures, due to the larger bound surface between the plastic packaging body and the lead frame and more uniform and reasonable stress, the new structural frame can effectively enhance the strength of the contact surface between the frame and the plastic packaging body, and improve the overall product structural strength. High reliability performance: when the product of the new lead frame structure has interfacial microcracks, the longer gap channels can effectively delay the occurrence of defects that lead to product failure, prolong the product life cycle, can be applied industrially and can meet the requirements of industrial application.

What is claimed is:

1. A method for manufacturing a lead frame, characterized in comprising:
Step A: providing a first plating resistant layer on the surface of a frame substrate, exposing and developing the first plating resistant layer to obtain a first recess;
Step B: adding layers by addition method, filling the first recess by electroplating, chemical deposition or sputtering to obtain a first protruding platform;
Step C: providing a second plating resistant layer on the first protruding platform and the first plating resistant layer, exposing and developing the second plating resistant layer to obtain a second recess which is located at the upper part of the first protruding platform, with a portion of the second recess located at the upper part of the first plating resistant layer;
Step D: adding layers by addition method, filling the second recess by electroplating, chemical deposition or sputtering to form a capping structure on the first protruding platform;
Step E: removing the first plating resistant layer and the second plating resistant layer.

2. The method for manufacturing the lead frame according to claim 1, characterized in further comprising after Step A and before Step B:
Step A1: treating the inner wall of the opening of the first recess using radio frequency plasma processing to increase its roughness.

3. The method for manufacturing the lead frame according to claim 2, characterized in that Step A1 comprises: controlling the roughness of the side wall of the first recess in the range of: Rz=2-3 μm, Ra=0.2-0.3 μm.

4. The method for manufacturing the lead frame according to claim 1, characterized in further comprising after Step C and before Step D:
Step C1: using dielectric barrier discharge (DBD) plasma processing to improve surface tension and hydrophilicity of the inner wall of the opening of the second recess.

5. The method for manufacturing the lead frame according to claim 4, characterized in that Step C1 further comprises: the strength of the DBD plasma processing at the corner where the first plating resistant layer and the second plating resistant layer bind being more than 10% greater than that of other portions, and the processing time being more than 10% longer than that of other portions.

6. The method for manufacturing the lead frame according to claim 5, characterized in that Step D comprises:
Step D1: adding layers by addition method, filling the second recess by electroplating, chemical deposition or sputtering to form a first metal layer of the capping structure on the first protruding platform.

7. The method for manufacturing the lead frame according to claim 6, characterized in that Step D further comprises after Step D1:
Step D2: adding layers by addition method, filling the second recess by electroplating, chemical deposition or sputtering to form a second metal layer of the capping structure on the first metal layer.

8. The method for manufacturing the lead frame according to claim 7, characterized in that the strength and hardness of the first metal layer are greater than those of the second metal layer.

9. The method for manufacturing the lead frame according to claim 8, characterized in that the first metal layer is a gold layer, a nickel-palladium gold layer, or a nickel layer, and the second metal layer is a copper layer.

10. The method for manufacturing the lead frame according to claim 5, characterized in that Step D comprises:
controlling the roughness of the inner wall of the second recess in the range of: Rz=2-3 μm, Ra=0.2-0.3 μm.
the thickness of the first metal layer being 3-5 μm.

11. The method for manufacturing the lead frame according to claim 1, characterized in that the Step E comprises:
removing the first plating resistant layer and second plating resistant layer by high pressure cleaning and APPA atmospheric pressure plasma cleaning;
introducing APPA atmospheric pressure plasma cleaning, which uses a plasma beam with a high energy density to directly act on the corner where the first plating resistant layer and the second plating resistant layer bind, separating any residual plating resistant material from the corner of the frame.

12. The method for manufacturing the lead frame according to claim 1, characterized in that the height of the first protruding platform is 80% to 95% of the depth of the first recess; the surface of the first protruding platform is roughened before the capping structure is produced; the capping structure includes a vertical portion and a platform portion, with the vertical portion located directly above the first protruding platform and the platform portion located at the upper part of the vertical portion.

13. The method for manufacturing the lead frame according to claim 12, characterized in that the bound surface between the first protruding platform and the capping structure is indented.

14. A lead frame structure, characterized in comprising a frame substrate, a first protruding platform, and a capping structure, wherein the first protruding platform is set on the frame substrate, the periphery of the first protruding platform is a recess, and the capping structure is set on the first protruding platform, and wherein at least a portion of the capping structure protrudes from the upper part of the first protruding platform and covers the recess.

15. The lead frame structure according to claim 14, characterized in that the number of the first protruding platform and the capping structure is both more than 2, with one first protruding platform corresponding to one capping structure.

16. The lead frame structure according to claim 15, characterized in that the first protruding platform is distributed in an array on the frame substrate.

17. The lead frame structure according to claim 16, characterized in that the capping structure, the first protruding platform, and the frame substrate form an I-shape structure.

18. The lead frame structure according to claim 17, characterized in that the side walls of the first protruding platform and the capping structure are arranged in a serrated shape.
